(19) United States
(12) Patent Application Publication
(10) Pub. No.: US 2025/0393407 A1
(43) Pub. Date: Dec. 25, 2025

(54) DISPLAY PANEL, DISPLAY DEVICE, ELECTRONIC DEVICE, AND METHOD OF MANUFACTURING THE SAME

(71) Applicant: Samsung Display Co., LTD., Yongin-si (KR)

(72) Inventor: HYUNGGUEN YOON, Yongin-si (KR)

(21) Appl. No.: 19/170,941

(22) Filed: Apr. 4, 2025

(30) Foreign Application Priority Data
Jun. 25, 2024 (KR) 10-2024-0083096

(51) Int. Cl. H10K 59/122; H10K 59/12; H10K 59/38; H10K 59/80

(52) U.S. Cl. CPC H10K 59/122; H10K 59/1201; H10K 59/38; H10K 59/878

(57) ABSTRACT

A display panel includes a base layer, a circuit element layer disposed on the base layer, a first layer disposed on the circuit element layer and including a first barrier wall provided with first openings defined therethrough, a reflective member including a first portion disposed in the first openings and covering an upper surface of the circuit element layer and side surfaces of the first barrier wall, which define the first openings, a first pattern including a first quantum dot and disposed on the first portion overlapping the first light emitting area, and a second pattern including a second quantum dot and disposed on the first portion overlapping a second light emitting area, and a second layer disposed on the first layer and including a second barrier wall provided with second-first openings defined therethrough to overlap the first openings and first light emitting patterns respectively disposed in the second-first openings.

This application claims priority to Korean Patent Application No. 10-2024-0083096, filed on Jun. 25, 2024, and all the benefits accruing therefrom under 35 U.S.C. § 119, the content of which in its entirety is herein incorporated by reference.

### BACKGROUND

### 1. Field

The invention generally relates to a display panel, and more particularly to a display panel including a quantum dot.

### 2. Description of Related Art

Various display devices are being developed to provide image information on multimedia devices such as televisions, mobile phones, tablet computers, navigation systems, and game consoles.

In particular, quantum dots are being introduced to improve display quality in a display device including a liquid crystal display element or an organic light emitting display element. Recently, methods to increase a light emission efficiency in the display device including quantum dots are being studied.

### SUMMARY

An embodiment provides a display panel with improved light emission efficiency.

An embodiment provides a method of manufacturing a display device including the display panel with improved light emission efficiency.

Embodiments provide a display panel including a base layer including first, second, and third light emitting areas and a non-light-emitting area disposed adjacent to the first, second, and third light emitting areas, a circuit element layer disposed on the base layer and including a transistor, a first layer disposed on the circuit element layer and including a first barrier wall provided with first openings defined therethrough, a reflective member including a first portion disposed in the first openings and covering an upper surface of the circuit element layer and side surfaces of the first barrier wall, which define the first openings, a first pattern including a first quantum dot and disposed on the first portion overlapping the first light emitting area, and a second pattern including a second quantum dot and disposed on the first portion overlapping the second light emitting area, and a second layer disposed on the first layer and including a second barrier wall provided with second-first openings defined therethrough to overlap the first openings and first light emitting patterns respectively disposed in the second-first openings.

In an embodiment, the first barrier wall is in contact with the upper surface of the circuit element layer.

In an embodiment, the reflective member includes a metal material.

In an embodiment, the first barrier wall has a surface energy greater than about 12 dyne/cm and smaller than about 20 dyne/cm.

In an embodiment, the second layer further includes first electrodes, one of the first electrodes is disposed between one of the first light emitting patterns and the first pattern, and another of the first electrodes is disposed between another of the first light emitting patterns and the second pattern.

In an embodiment, the first electrodes includes an indium tin oxide and has a light transmittance equal to or greater than about 90%.

In an embodiment, the display panel further includes a third layer disposed on the second layer. The third layer includes first, second, and third half mirror layers, a first medium layer disposed between the first half mirror layer and the second half mirror layer, and a second medium layer disposed between the second half mirror layer and the third half mirror layer.

In an embodiment, each of the first and second medium layers includes a resin or silicon nitride having a light transmissivity.

In an embodiment, the display panel further includes a fourth layer disposed on the third layer where the fourth layer includes a third barrier wall provided with third-first openings defined therethrough, a first color filter disposed in one of the third-first openings and overlapping the first pattern, and a second color filter disposed in another of the third-first openings and overlapping the second pattern.

In an embodiment, the first color filter has a light transmissivity with respect to a red light.

In an embodiment, the second color filter has a light transmissivity with respect to a green light.

In an embodiment, the second barrier wall is provided with a second-second opening defined therethrough to overlap the third light emitting area, the second layer further includes a second light emitting pattern disposed in the second-second opening and a first electrode disposed between the first barrier wall and the second light emitting pattern, and the reflective member further includes a second portion overlapping the third light emitting area and disposed between the first electrode and the first barrier wall.

In an embodiment, the third barrier wall is provided with a third-second opening defined therethrough to overlap the second light emitting pattern.

In an embodiment, the fourth layer further includes a third color filter disposed in the third-second opening and having a light transmissivity with respect to a blue light.

In an embodiment, the second and third barrier walls include a light blocking material.

In an embodiment, the reflective member further includes a second portion covering an upper surface of the first barrier wall, and the first portion and the second portion are provided integrally with each other.

In an embodiment, the second barrier wall has a surface energy greater than about 12 dyne/cm and smaller than about 20 dyne/cm.

Embodiments provide a method of manufacturing a display device, where the method includes providing a base layer and a circuit element layer disposed on the base layer and including transistors, forming a first barrier wall through which first openings are defined on the circuit element layer, forming a reflective member base on the first barrier wall, removing at least a portion of the reflective member base, which is in contact with an upper surface of the first barrier wall, to form a reflective member, forming a first pattern including a quantum dot on the reflective member covering the first openings, forming first electrodes on the first pattern, forming a second barrier wall through which second-first openings are defined to overlap the first openings on the first barrier wall, forming first light emitting patterns in the second-first openings, and forming a half mirror layer on the second barrier wall.

In an embodiment, the forming of the first pattern includes spraying an ink including the quantum dot to the first opening.

In an embodiment, the first barrier wall has a surface energy greater than about 12 dyne/cm and smaller than about 20 dyne/cm.

In an embodiment, the forming of the second barrier wall further includes forming a second-second opening that does not overlap the first openings.

In an embodiment, the method further includes forming a second light emitting pattern in the second-second opening after the forming of the second barrier wall.

Embodiments provide a method of manufacturing a display device, where the method includes providing a base layer and a circuit element layer disposed on the base layer and including transistors, forming a first barrier wall through which first openings are defined on the circuit element layer, forming a reflective member on the first barrier wall, forming a second barrier wall through which second openings are defined to overlap the first openings on the first barrier wall, forming patterns including a quantum dot on the reflective member covering the first openings, forming first electrodes on the patterns, forming light emitting patterns in the second openings, and forming a first half mirror layer on the second barrier wall.

In an embodiment, the forming of the pattern including the quantum dot includes spraying an ink including the quantum dot to the first openings.

In an embodiment, the second barrier wall has a surface energy greater than about 12 dyne/cm and smaller than about 20 dyne/cm.

In an embodiment and according to the above, the display panel generates a light recycling effect and improves a light emission efficiency.

In an embodiment and according to the above, the display device with light recycling effect and improved light emission efficiency is manufactured.

### BRIEF DESCRIPTION OF THE DRAWINGS

The above and other advantages of the invention will become readily apparent by reference to the following detailed description when considered in conjunction with the accompanying drawings wherein:

FIG. 1 is a perspective view of a display device. according to an embodiment;

FIG. 2 is a cross-sectional view taken along a line I-I′ of FIG. 1, according to an embodiment;

FIG. 3 is a plan view of a display panel, according to an embodiment;

FIG. 4 is a circuit diagram of a pixel, according to an embodiment;

FIG. 5 is a plan view of pixels, according to an embodiment;

FIG. 6 is a cross-sectional view taken along a line II-II′ of FIG. 5, according to an embodiment;

FIG. 7A is an enlarged cross-sectional view of an area of FIG. 6, according to an embodiment;

FIG. 7B is an enlarged cross-sectional view of an area of FIG. 6, according to an embodiment;

FIG. 7C is an enlarged cross-sectional view of an area of FIG. 6, according to an embodiment;

FIG. 8A is a view illustrating a method of manufacturing a display device, according to an embodiment;

FIG. 8B is a view illustrating a method of manufacturing a display device, according to an embodiment;

FIG. 8C is a view illustrating a method of manufacturing a display device, according to an embodiment;

FIG. 8D is a view illustrating a method of manufacturing a display device, according to an embodiment;

FIG. 8E is a view illustrating a method of manufacturing a display device, according to an embodiment;

FIG. 8F is a view illustrating a method of manufacturing a display device, according to an embodiment;

FIG. 8G is a view illustrating a method of manufacturing a display device, according to an embodiment;

FIG. 8H is a view illustrating a method of manufacturing a display device, according to an embodiment;

FIG. 8I is a view illustrating a method of manufacturing a display device, according to an embodiment;

FIG. 8J is a view illustrating a method of manufacturing a display device, according to an embodiment;

FIG. 8K is a view illustrating a method of manufacturing a display device, according to an embodiment;

FIG. 9 is a cross-sectional view of a display panel, according to an embodiment;

FIG. 10A is a view illustrating a method of manufacturing a display device, according to an embodiment.

FIG. 10B is a view illustrating a method of manufacturing a display device, according to an embodiment; and

FIG. 10C is a view illustrating a method of manufacturing a display device, according to an embodiment.

### DETAILED DESCRIPTION

The invention may be variously modified and realized in many different forms, and thus specific embodiments will be exemplified in the drawings and described in detail hereinbelow. However, the invention should not be limited to the specific disclosed forms, and should be construed to include all modifications, equivalents, or replacements included in the spirit and scope of the invention.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described with reference to accompanying drawings.

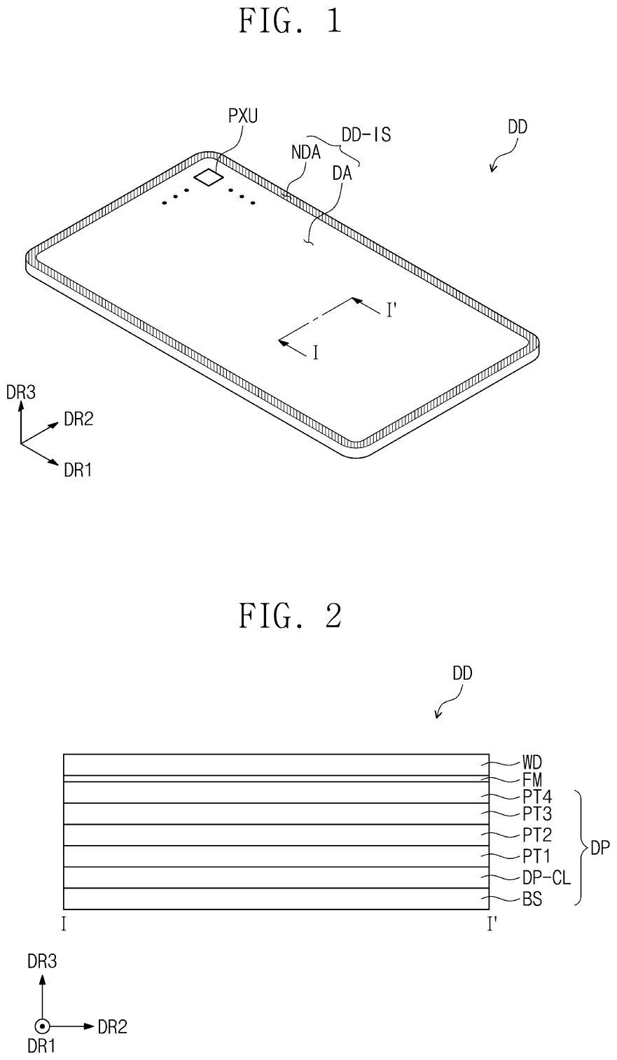

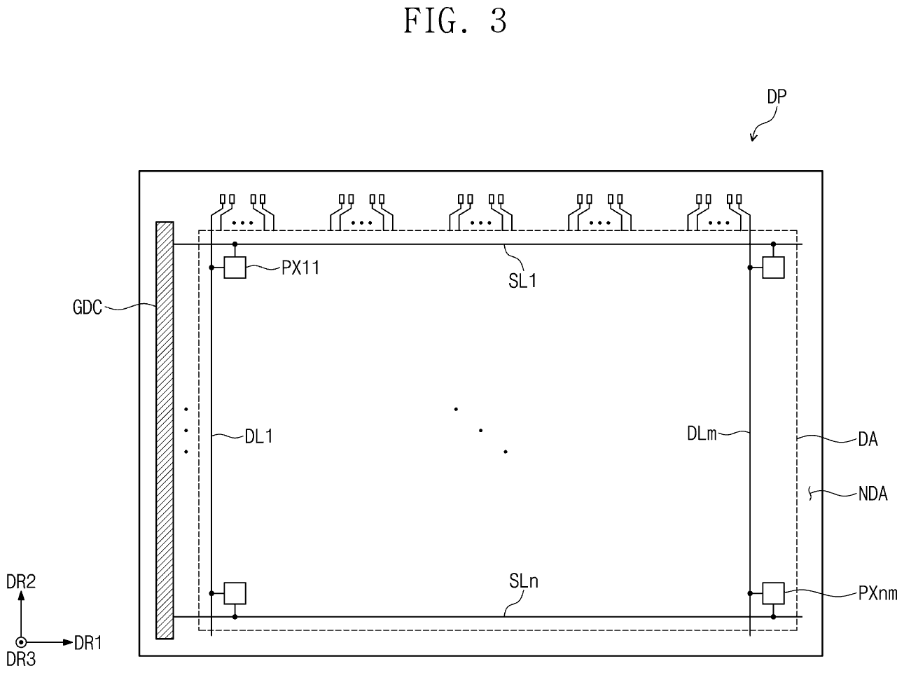

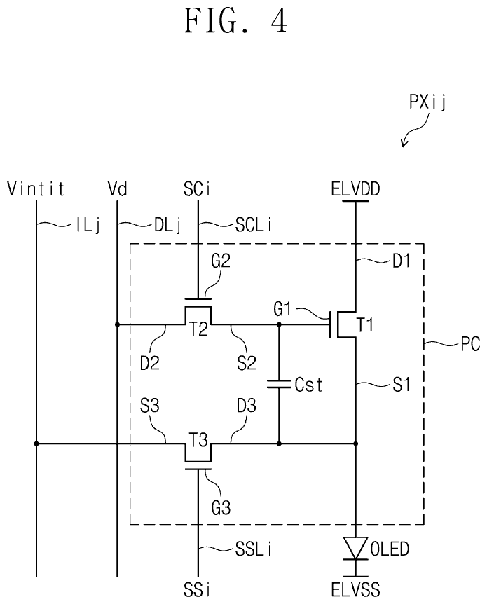

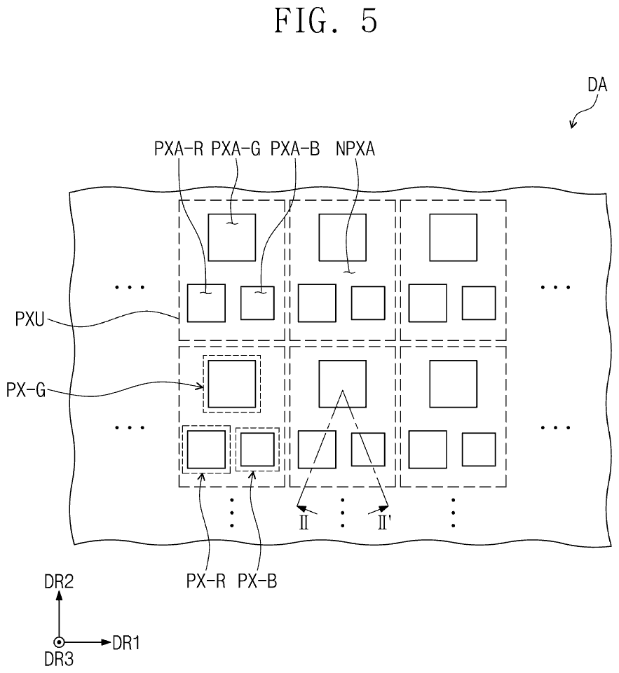

FIG. 1 is a perspective view of a display device DD, according to an embodiment. FIG. 2 is a cross-sectional view taken along a line I-I′ of FIG. 1. FIG. 3 is a plan view of a display panel DP according to an embodiment. FIG. 4 is a circuit diagram of a pixel PXij according to an embodiment. FIG. 5 is a plan view of pixels according to an embodiment.

Referring to FIG. 1, the display device DD may display an image through a display surface DD-IS. An upper surface of a member disposed at an uppermost position of the display device DD may be defined as the display surface DD-IS. According to the present disclosure, an upper surface of a window WD shown in FIG. 2 may be provided as the display surface DD-IS of the display device DD.

The display surface DD-IS may be substantially parallel to a plane defined by a first direction DR1 and a second direction DR2. A third direction DR3 may indicate a normal line direction of the display surface DD-IS, i.e., a thickness direction of the display device DD. Front (or upper) and rear (or lower) surfaces of each layer or each unit may be distinguished from each other in the third direction DR3.

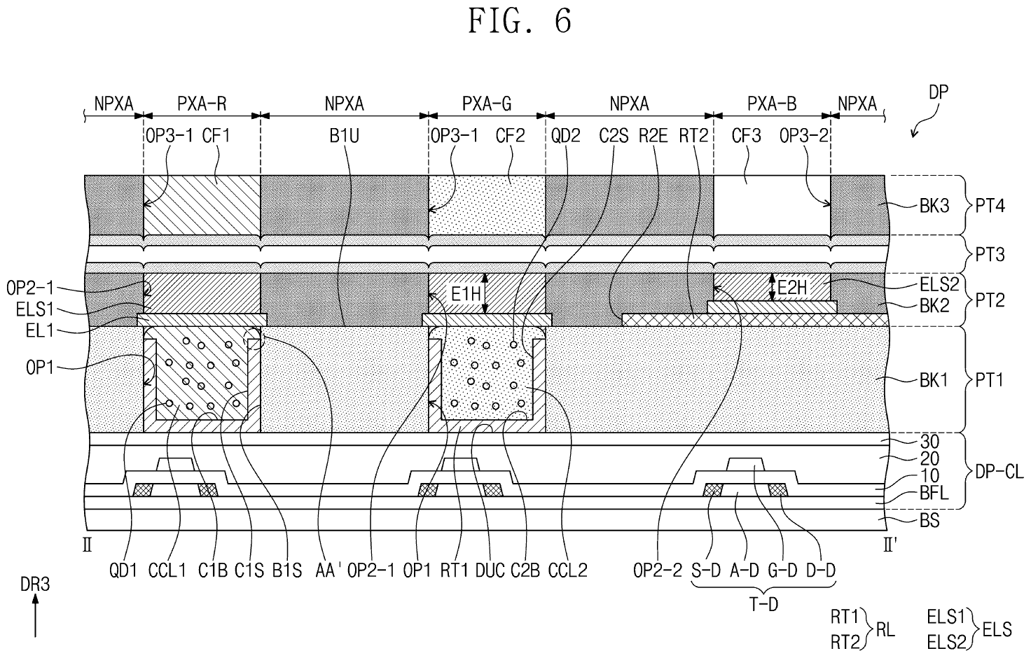

The display device DD may include a display area DA and a non-display area NDA. Light emitting patterns (refer to ELS of FIG. 6) included in each pixel (refer to PX11 to PXnm of FIG. 3) may be arranged in the display area DA, and the light emitting patterns (refer to ELS of FIG. 6) included in each pixel (refer to PX11 to PXnm of FIG. 3) may not be arranged in the non-display area NDA. The non-display area NDA may be defined along an edge of the display surface DD-IS. The non-display area NDA may surround the display area DA. According to an embodiment, the non-display area NDA may be omitted or may be defined to be adjacent to only one side of the display area DA.

FIG. 1 shows a structure in which a unit pixel PXU is disposed in the display area DA. The unit pixel PXU may include at least two pixels emitting different lights from each other. As an example, the unit pixel PXU may be an area where pixels emitting a source light are arranged. The light emission size, shape, and arrangement of the pixels included in the unit pixel PXU should not be particularly limited. As an example, the pixels included in the unit pixel PXU may have different light emission sizes from each other. In addition, each of light emitting areas may have a circular shape or a polygonal shape when viewed in a plane.

Referring to FIG. 2, the display device DD may include the display panel DP, the window WD, and a filler FM disposed between the display panel DP and the window WD. The display panel DP may include a base layer BS, a circuit element layer DP-CL, and first, second, third, and fourth layers PT1, PT2, PT3, and PT4, respectively.

The base layer BS may include a synthetic resin layer. The synthetic resin layer may include a thermosetting resin. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In addition, the base layer BS may include a glass substrate, a metal substrate, or an organic/inorganic composite material substrate.

The circuit element layer DP-CL may include an insulating layer, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned through several photolithography processes. Accordingly, the semiconductor pattern, the conductive pattern, and the signal line included in the circuit element layer DP-CL may be formed. Patterns disposed on the same layer may be formed through the same process. The circuit element layer DP-CL may include a driving circuit or a signal line to form a pixel (refer to PXij of FIG. 4).

The layers PT1, PT2, PT3, and PT4 may be sequentially stacked. The first layer PT1 may include a quantum dot to change a color of a source light, the second layer PT2 may provide the source light, the third layer PT3 may micro-resonate the light provided from the first layer PT1 or the second layer PT2 to improve the light emission efficiency. The third layer PT3 may include a Fabry-Perot interferometer (FPI). The fourth layer PT4 may include a color filter that filters the emitted light to improve a color purity of the light.

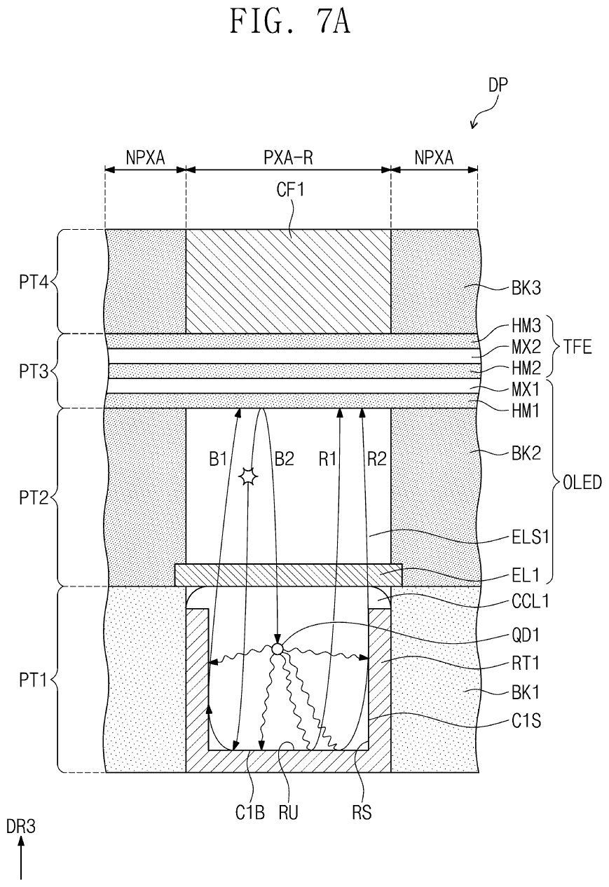

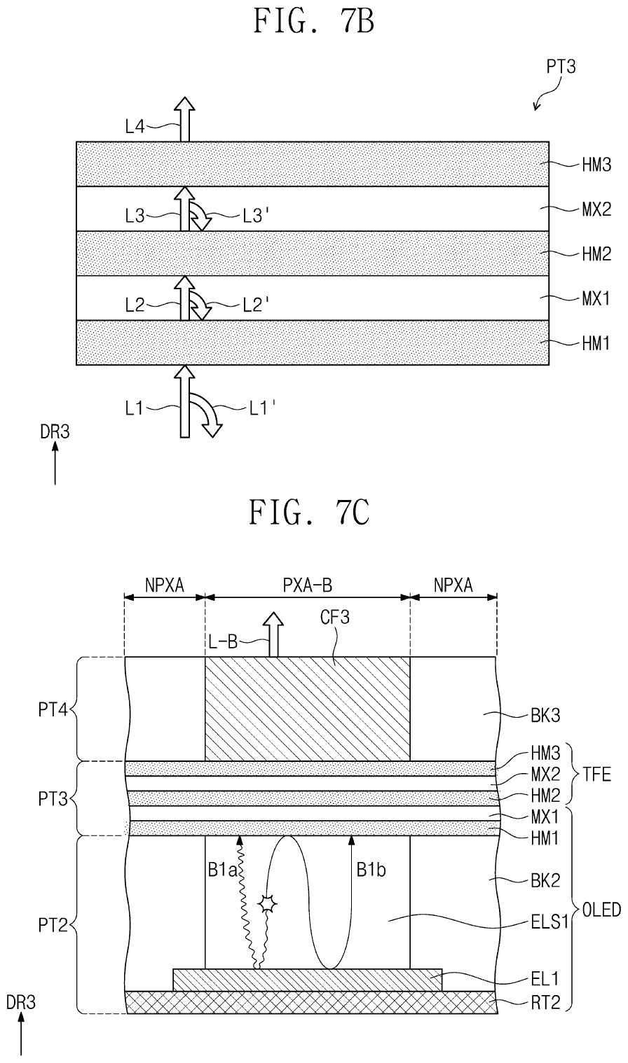

The display panel DP may perform light recycling of the source light through the structure in which the layers PT1, PT2, PT3, and PT4 are stacked and may improve the light emission efficiency using a resonance effect. In the present disclosure, the term “light recycling” may refer to the reconversion or reflection of light that is not converted to a specific wavelength or is not emitted through the front of the display panel DP. The layers PT1, PT2, PT3, and PT4 will be described in detail with reference to FIGS. 6 to 7C.

The window WD may be disposed on the fourth layer PT4. The window WD may transmit the image provided from the display panel DP to the outside. As shown in FIG. 1, the display surface DD-IS that is defined as the upper surface of the window WD may be divided into the display area DA and the non-display area NDA. A boundary between the display area DA and the non-display area NDA may be defined by a bezel pattern absorbing a light and disposed under the window WD. Although not shown separately, the window WD may include a base layer and functional layers disposed on the base layer. The functional layers may include a protective layer, an anti-reflective layer, and the like. The base layer of the window WD may be formed of glass, sapphire, or plastic.

FIG. 3 shows an arrangement relationship of signal lines SLI to SLn and DL1 to DLm and pixels PX11 to PXnm on a plan view. The signal lines SLI to SLn and DL1 to DLm may include a plurality of scan lines SLI to SLn and a plurality of data lines DLI to DLm.

The pixels PX11 to PXnm may be arranged in the display area DA. Each of the pixels PX11 to PXnm may be connected to a corresponding scan line of the scan lines SLI to SLn and a corresponding data line of the data lines DLI to DLm. Each of the pixels PX11 to PXnm may include a pixel circuit and a light emitting element. More types of signal lines may be provided in the display device DD depending on the configuration of the pixel circuit of the pixels PX11 to PXnm.

A gate driving circuit GDC may be disposed in the non-display area NDA. The gate driving circuit GDC may be integrated in the display device DD through an oxide silicon gate driver circuit (OSG) process or an amorphous silicon gate driver circuit (ASG) process.

FIG. 4 is an equivalent circuit diagram of the pixel PXij among the pixels PX11 to PXnm (refer to FIG. 3) as a representative example. The pixel PXij may include a pixel circuit PC and a light emitting element OLED. The pixel circuit PC may include a plurality of transistors T1, T2 and T3 and a capacitor Cst.

The transistors T1 to T3 may be formed through a low temperature polycrystalline silicon (LTPS) process or a low temperature polycrystalline oxide (LTPO) process. Each of transistors T1 to T3 may include one of a silicon semiconductor and an oxide semiconductor. In this case, the oxide semiconductor may include a crystalline or amorphous oxide semiconductor, and the silicon semiconductor may include amorphous silicon, polycrystalline silicon, or the like, however, the invention should not be particularly limited.

Hereinafter, the transistors T1 to T3 will be described as an N-type transistor, however, it should not be limited thereto or thereby. Each of the transistors T1 to T3 may be a P-type transistor or the N-type transistor depending on a signal applied thereto. In this case, a source and a drain of the P-type transistor may correspond to a source and a drain of the N-type transistor, respectively.

FIG. 4 shows the pixel PXij connected to an i-th scan line SCLi, an i-th sensing line SSLi, a j-th data line DLj, and a j-th initial line ILj as a representative example.

The pixel circuit PC may include the first transistor T1 (a driving transistor), the second transistor T2 (a switching transistor), the third transistor T3 (a sensing transistor), and the capacitor Cst. According to an embodiment, the pixel circuit PC may further include an additional transistor and an additional capacitor, and the pixel circuit PC should not be limited thereto or thereby.

The light emitting element OLED may be an organic light emitting element, which includes an anode (a first electrode) and a cathode (a second electrode), or an inorganic light emitting element. The anode of the light emitting element OLED may receive a first voltage ELVDD via the first transistor T1, and the cathode of the light emitting element OLED may receive a second voltage ELVSS. The light emitting element OLED may emit the light in response to the first voltage ELVDD and the second voltage ELVSS.

The first transistor T1 may include a drain D1 receiving the first voltage ELVDD, a source S1 connected to the anode of the light emitting element OLED, and a gate G1 connected to the capacitor Cst. The first transistor T1 may control a driving current flowing from the first voltage ELVDD to the light emitting element OLED in response to a level of a voltage charged in the capacitor Cst.

The second transistor T2 may include a drain D2 connected to the j-th data line DLj, a source S2 connected to the capacitor Cst, and a gate G2 receiving an i-th first scan signal SCi. The second transistor T2 may apply a data voltage Vd to the first transistor T1 in response to the i-th first scan signal SCi.

The third transistor T3 may include a source S3 connected to the j-th initial line ILj, a drain D3 connected to the anode of the light emitting element OLED, and a gate G3 receiving an i-th second scan signal SSi. The j-th initial line ILj may receive an initial voltage Vintit.

The capacitor Cst may be charged with electric charges corresponding to a difference between various voltages according to input signals. As an example, the capacitor Cst may be charged with electric charges corresponding to a difference between the voltage from the second transistor T2 and the first voltage ELVDD.

As shown in FIG. 5, a light generated from a first pixel PX-R may be provided to a first light emitting area PXA-R, a light generated from a second pixel PX-G may be provided to a second light emitting area PXA-G, and a light generated from a third pixel PX-B may be provided to a third light emitting area PXA-B. The light emitting areas PXA-R, PXA-G, and PXA-B may correspond to third-first openings OP3-1 and a third-second opening OP3-2 defined through a third barrier wall BK3, which is described with reference to FIG. 6.

A non-light-emitting area NPXA may be defined between the light emitting areas PXA-R, PXA-G, and PXA-B. The non-light-emitting area NPXA may define a boundary of the light emitting areas PXA-R, PXA-G, and PXA-B and may prevent a color mixture between the light emitting areas PXA-R, PXA-G, and PXA-B.

Each of the pixels PX-R, PX-G, and PX-B may include the light emitting element OLED (refer to FIG. 6). The source lights generated by the light emitting elements OLED (refer to FIG. 6) of the first, second, and third pixels PX-R, PX-G, and PX-B may be emitted through the first light emitting area PXA-R, the second light emitting area PXA-G, and the third light emitting area PXA-B.

Referring to FIG. 5, the first light emitting area PXA-R and the third light emitting area PXA-B may be arranged in the same row, and the second light emitting area PXA-G may be arranged in a row different from the row in which the first light emitting area PXA-R and the third light emitting area PXA-B are arranged. As an example, the first light emitting area PXA-R and the third light emitting area PXA-B may be arranged spaced apart from each other in the first direction DR1, and the second light emitting area PXA-G may be disposed spaced apart from the first light emitting area PXA-R and the third light emitting area PXA-B in a diagonal direction of each of the first direction DR1 and the second direction DR2.

The arrangement of the first light emitting area PXA-R, the second light emitting area PXA-G, and the third light emitting area PXA-B disposed in the unit pixel PXU shown in FIG. 5 is merely an example, and the invention should not be limited thereto or thereby. According to an embodiment, the first light emitting area PXA-R, the second light emitting area PXA-G, and the third light emitting area PXA-B may be arranged in the same row along the first direction DR1. In addition, the arrangement of the first light emitting area PXA-R, second light emitting area PXA-G, and third light emitting area PXA-B may be changed depending on the unit pixels PXU.

In an embodiment, the first light emitting area PXA-R may have a size smaller than a size of the second light emitting area PXA-G and greater than a size of the third light emitting area PXA-B. However, the sizes of the light emitting areas PXA-R, PXA-G, and PXA-B should not be limited thereto or thereby.

In an embodiment, the first light emitting area PXA-R, the second light emitting area PXA-G, and the third light emitting area PXA-B may have a square shape. However, the arrangement and the size of the light emitting areas should not be limited thereto or thereby.

FIG. 6 is a cross-sectional view taken along a line II-II′ of FIG. 5. Hereinafter, a stack structure of the display panel DP will be described with reference to FIG. 6.

Referring to FIG. 6, the display panel DP may include the base layer BS, the circuit element layer DP-CL, the first layer PT1, the second layer PT2, the third layer PT3, and the fourth layer PT4.

The base layer BS may provide a base surface on which a buffer layer BFL, insulating layers 10, 20, and 30, and transistors T-D, which are included in the circuit element layer DP-CL, are disposed. As shown in FIG. 6, the base layer may have a single-layer structure, however, according to an embodiment, the base layer BS may have a multi-layer structure in which an organic layer and an inorganic layer are sequentially stacked, and it should not be particularly limited.

The circuit element layer DP-CL may be disposed on the base layer BS. The circuit element layer DP-CL may include the buffer layer BFL, the first insulating layer 10, the second insulating layer 20, the third insulating layer 30, and the transistor T-D. The transistor T-D may be one of the transistors T1 to T3 described with reference to FIG. 4. However, the structure of the circuit element layer DP-CL should not be limited to that of FIG. 6. As an example, the circuit element layer DP-CL may further include light blocking patterns (not shown) disposed on the base layer BS.

The buffer layer BFL may be disposed on the base layer BS. The buffer layer BFL may increase an adhesive force between the base layer BS and the semiconductor pattern. The buffer layer BFL may include an inorganic material.

The first insulating layer 10 may be disposed on the base layer BS. The first insulating layer 10 may include an inorganic material. As an example, the inorganic material may include a silicon oxide layer and a silicon nitride layer. Each of the silicon oxide layer and the silicon nitride layer may be provided in plural, and the silicon oxide layers may be alternately stacked with the silicon nitride layers.

The transistor T-D may include an active A-D, a source S-D, a drain D-D, and a gate G-D. The active A-D, the source S-D, and the drain D-D may be disposed on the first insulating layer 10. The active A-D, the source S-D, and the drain D-D may be distinguished from each other depending on a doping concentration or a conductivity of the semiconductor pattern. The transistor T-D may be directly or indirectly connected to a first electrode EL1 described later. Although not shown separately, the transistor T-D may be connected to the first electrode EL1 via a contact hole defined through a first barrier wall BK1 described later.

The second insulating layer 20 may be disposed on the first insulating layer 10 and may cover the active A-D, the source S-D, and the drain D-D. The second insulating layer 20 may be disposed between the gate G-D and the active A-D, the source S-D, and the drain D-D.

The second insulating layer 20 may include an organic material. The second insulating layer 20 may include an organic layer and may provide a flat upper surface. However, the material and structure of the second insulating layer 20 should not be particularly limited.

The gate G-D may be disposed on the second insulating layer 20. The gate G-D may include metal layers sequentially stacked one on another. A first layer of metal layer may include titanium, and a second layer of metal layer may include copper.

The third insulating layer 30 may be disposed on the first insulating layer 10 and the second insulating layer 20 and may cover the gate G-D.

The third insulating layer 30 may include an inorganic material. As an example, the inorganic material may include a silicon oxide layer and a silicon nitride layer. Each of the silicon oxide layer and the silicon nitride layer may be provided in plural, and the silicon oxide layers may be alternately stacked with the silicon nitride layers. However, the material and structure of the third insulating layer 30 should not be particularly limited.

The first layer PT1 may be disposed on the circuit element layer DP-CL. The first layer PT1 may include the first barrier wall BK1, a reflective member RL, a first pattern CCL1, and a second pattern CCL2.

The first barrier wall BK1 may be disposed on the circuit element layer DP-CL. The first barrier wall BK1 may be directly in contact with an upper surface DCU of the circuit element layer DP-CL. That is, no other component is disposed between the first barrier wall BK1 and the circuit element layer DP-CL.

The first barrier wall BK1 may include a polymer resin. As an example, the first barrier wall BK1 may include a polyacrylate-based resin or a polyimide-based resin. In addition, the first barrier wall BK1 may further include an inorganic material in addition to the polymer resin. According to an embodiment, the first barrier wall BK1 may be formed of an inorganic material. As an example, the first barrier wall BK1 may include silicon nitride (SiNₓ), silicon oxide (SiOₓ), or silicon oxynitride (SiOₓN_{y}).

The first barrier wall BK1 may be provided with first openings OP1 defined therethrough. The first openings OP1 may overlap the first light emitting area PXA-R and the second light emitting area PXA-G. The first openings OP1 may be formed penetrating the first barrier wall BK1.

The reflective member RL may include first portions RT1 respectively disposed in the first openings OP1 and covering the upper surface DUC of the circuit element layer DP-CL and side surfaces BIS of the first barrier wall BK1, which defines the first openings OP1, and a second portion RT2 overlapping the third light emitting area PXA-B and disposed between the first electrode EL1 and the first barrier wall BK1. An edge R2E of the second portion RT2 may overlap the non-light emitting area NPXA. The reflective member RL may have a function of reflecting a light. In detail, the reflective member RL may reflect a source light emitted from the light emitting pattern ELS described later or may re-reflect a light reflected by the third layer PT3. In an embodiment, the reflective member RL may reflect about 90% or more of a visible light.

The reflective member RL may include a metal material. The reflective member RL may include aluminum (Al), silver (Ag), magnesium (Mg), an alloy of magnesium (Mg) and silver (Ag), etc. However, the type of metal material contained in the reflective member RL should not be particularly limited as long as the reflective member RL has the property of reflecting light.

The first pattern CCL1 may be disposed in one of the first openings OP1. The first pattern CCL1 may overlap the first light emitting area PXA-R. The first pattern CCL1 may be disposed on the first portion RT1. The first pattern CCL1 may change an optical property of the source light.

The first pattern CCL1 may include a first quantum dot QD1 that changes the optical property of the source light. The first quantum dot QD1 may convert the source light into a light of different wavelengths. As an example, the first quantum dot QD1 may convert the source light into a red light.

The second pattern CCL2 may be disposed in another of the first openings OP1. The second pattern CCL2 may overlap the second light emitting area PXA-G. The second pattern CCL2 may be disposed on the first portion RT1. The second pattern CCL2 may change the optical property of the source light.

The second pattern CCL2 may include a second quantum dot QD2 that changes the optical property of the source light. The second quantum dot QD2 convert the source light into a light of different wavelengths. As an example, the second quantum dot QD2 may convert the source light into a green light.

In an embodiment, the quantum dot refers to a crystal of a semiconductor compound. The quantum dot may emit light of various light-emitting wavelengths according to the size of the crystal thereof. The quantum dot may emit light of various emission wavelengths by adjusting the ratio of elements in the quantum dot compound.

The quantum dot may have a diameter within a range of about 1 nm to about 10 nm. The quantum dot may be synthesized by a wet chemical process, a metal organic chemical vapor deposition process, a molecular beam epitaxy process, or similar processes.

The wet chemical process is a method of growing quantum dot particle crystals after mixing an organic solvent with a precursor material. When the crystals grow, the organic solvent may naturally serve as a dispersant coordinated to the surface of the quantum dot crystal and may control the growth of the crystals. Accordingly, when compared with the vapor deposition methods, such as the metal organic chemical vapor deposition (MOCVD) process or the molecular beam epitaxy (MBE) process, the wet chemical process may be easier to control the growth of quantum dot particles through a low-cost process.

The quantum dots may include a group II-VI compound, a group III-V compound, a group III-VI compound, a group I-III-VI compound, a group IV-VI compound, a group IV element, a group IV compound, or an arbitrary combination thereof.

The group II-VI compound may be selected from a binary compound such as CdSe, CdTe, CdS, ZnS, ZnSe, ZnTe, ZnO, HgS, HgSe, HgTe, MgSe, MgS, and a mixture thereof, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. Meanwhile, the group II-VI compound may further include a group I metal and/or a group IV element. The group I-II-VI compound may be selected from CuSnS or CuZnS, and the group II-IV-VI compound may be selected from ZnSnS. The group I-II-IV-VI compound may be selected from a quaternary compound selected from the group consisting of Cu2ZnSnS2, Cu2ZnSnS4, Cu2ZnSnSe4, Ag2ZnSnS2, and a mixture thereof.

The group III-VI compound may include a binary compound, such as In2S3, In2Se3, etc., a ternary compound, such as InGaS3, InGaSe3, etc., or an arbitrary combination thereof.

The group I-III-VI compound may include a ternary compound selected from the group consisting of AgInS, AgInS2, CuInS, CuInS2, AgGaS2, CuGaS2 CuGaO2, AgGaO2, AgAIO2, and a mixture thereof, or a quaternary compound of AgInGaS2, CuInGaS2, or the like.

The group III-V compound may be selected from a binary compound selected from the group consisting of GaN, GaP, GaAs, GaSb, AlN, AIP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAIP, InNP, InNAs, InNSb, InPAs, InPSb, and a mixture thereof, and a quaternary compound selected from the group consisting of GaAINP, GaAINAs, GaAINSb, GaAlPAs, GaAlPSb, GaInNP, GalInNAs, GaInNSb, GalnPAs, GalInPSb, InAINP, InAINAs, InAINSb, InAlPAs, InAlPSb, and a mixture thereof. The group III-V compound may further include a group II metal. For instance, InZnP may be selected as a group III-II-V compound.

The group IV-VI compound may be selected from a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

The group II-IV-V compound may include a ternary compound selected from the group consisting of ZnSnP, ZnSnP2, ZnSnAs2, ZnGeP2, ZnGeAs2, CdSnP2, CdGeP2, and a mixture thereof.

The group IV element may be selected from the group consisting of Si, Ge, and a mixture thereof. The group IV compound may be a binary compound selected from the group consisting of SiC, SiGe, and a mixture thereof.

In an embodiment, each element included in a multi-element compound, such as the binary compound, the ternary compound, or the quaternary compound, may be present in the particles at a uniform or non-uniform concentration. That is, the above chemical formula means the types of elements included in the compound, and an element ratio in the compound may be variable. As an example, AgInGaS2 may mean AgInxGa1-xS2 (x is a real number between 0 to 1).

In an embodiment, the binary compound, the ternary compound, or the quaternary compound may exist in the particles at a uniform concentration or may exist in the same particle after being divided into plural portions having different concentrations. In addition, one quantum dot may have a core/shell structure in which one quantum dot surrounds another quantum dot. In the core/shell structure, the concentration of elements existing in the shell may have a concentration gradient that is lowered as a distance from the core decreases.

In some embodiments, the quantum dot may have a core-shell structure that includes a core including the above-mentioned nanocrystal and a shell surrounding the core. The shell of the quantum dot may serve as a protective layer to prevent chemical modification of the core and to maintain semiconductor properties and/or may serve as a charging layer to impart electrophoretic properties to the quantum dot. The shell may have a single-layer or multi-layer structure. The shell of the quantum dot may include metal oxides, non-metal oxides, semiconductor compounds, or combinations thereof.

In an embodiment, the metal oxides or non-metal oxides may include a binary compound, such as SiO2, Al₂O₃, TiO₂, ZnO, MnO, Mn2O3, Mn3O4, CuO, FeO, Fe2O3, Fe3O4, CoO, Co3O4, NiO, etc., or a ternary compound, such as MgAl2O4, CoFe2O4, NiFe2O4, CoMn2O4, etc., however, they should not be limited thereto or thereby.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, however, they should not be limited thereto or thereby.

In an embodiment, the quantum dots may have a full width at half maximum (FWHM) of a light emission wavelength spectrum of about 45 nm or less, preferably about 40 nm or less, and more preferably about 30 nm or less. The color purity and the color reproducibility may be improved within this range. In addition, since the light emitted through the quantum dots may be emitted in all directions, an optical viewing angle may be improved.

In an embodiment, the shape of the quantum dots may have a shape commonly used in the art, and it should not be particularly limited. In more detail, spherical, pyramidal, multi-arm, or cubic nanoparticles, nanotubes, nanowires, nanofibers, nanoplatelets, or the like may be applied to the quantum dots.

Since the energy band gap may be adjusted by controlling the size of the quantum dot or the element ratio in the compounds for the quantum dot, lights having various wavelengths may be obtained from a quantum dot light-emitting layer. Accordingly, the light emitting element that emits the lights of various wavelengths may be implemented by using the above described quantum dots, i.e., the quantum dots having different sizes or the quantum dots having the compounds with different elements ratios. In detail, the size of the quantum dot or the element ratio of the compounds for the quantum dot may be selected to emit the red, green and/or blue lights. In addition, the quantum dot may be configured to emit a white light by combination of the lights having various colors.

The smaller the particle size of the quantum dot, the more it emits light in the short-wavelength range. For example, in the quantum dots having the same core, the particle size of the quantum dot emitting the green light may be smaller than the particle size of the quantum dot emitting the red light. In addition, in the quantum dots having the same core, the particle size of the quantum dot emitting the blue light may be smaller than the particle size of the quantum dot emitting the green light. However, the invention should not be limited thereto or thereby, and even in the quantum dots having the same core, the particle size may be adjusted according to the forming-material and thickness of the shell.

In an embodiment, when the quantum dots have various light emission colors such as blue, red, green, etc., the quantum dots having different emission colors may have different core materials.

In an embodiment, each of the first pattern CCL1 and the second pattern CCL2 may include scatterers and a base resin in which the scatterers are dispersed.

The first pattern CCL1 may be formed by spraying an ink including the first quantum dot QD1 to the first opening OP1 using an inkjet process, and the second pattern CCL2 may be formed by spraying an ink including the second quantum dot QD2 to a first opening OP1 using an inkjet process. The method of manufacturing the first pattern CCL1 and the second pattern CCL2 will be described in detail later.

In an embodiment, an inner space of the first opening OP1 may have a hexahedral shape. In this case, five surfaces of the first pattern CCL1 may be in contact with the first portion RT1. In detail, the five surfaces of the first pattern CCL1, which are in contact with the first portion RT1 may be defined as one bottom surface C1B and four side surfaces C1S.

In an embodiment, an inner space of the second opening OP2 may have a hexahedral shape. In this case, five surfaces of the second pattern CCL2 may be in contact with the second portion RT2. In detail, the five surfaces of the second pattern CCL2, which are in contact with the second portion RT2, may be defined as one bottom surface C2B and four side surfaces C2S.

The second layer PT2 may be disposed on the first layer PT1. The second layer PT2 may include a second barrier wall BK2, the light emitting pattern ELS, the first electrodes EL1, and the second portion RT2.

In an embodiment, the second barrier wall BK2 may be disposed on the first layer PT1.

The second barrier wall BK2 may be a pattern with a black color. The second barrier wall BK2 may be formed of a polymer resin. As an example, the second barrier wall BK2 may include a polyacrylate-based resin or a polyimide-based resin. In addition, the second barrier wall BK2 may further include an inorganic material in addition to the polymer resin. However, it should not be limited thereto or thereby, and the second barrier wall BK2 may be formed of an inorganic material. As an example, the second barrier wall BK2 may include silicon nitride (SiNₓ), silicon oxide (SiOₓ), or silicon oxynitride (SiOₓN_{y}).

The second barrier wall BK2 may include a black coloring agent. The black coloring agent may include a black dye or a black pigment. According to an embodiment, the black coloring agent may include a metal material, such as carbon black, chromium, or an oxide thereof. Accordingly, the second barrier wall BK2 may prevent a color mixture between the light emitting areas PXA-R, PXA-G, and PXA-B.

The second barrier wall BK2 may be provided with second-first openings OP2-1 defined therethrough to respectively overlap the first openings OP1 and a second-second opening OP2-2 defined therethrough to overlap the third light emitting area PXA-B and not to overlap the first openings OP1.

In an embodiment, the second layer PT2 may further include a second light emitting pattern ELS2 disposed in the second-second opening OP2-2 and the first electrode EL1 disposed between the first barrier wall BK1 and the second light emitting pattern ELS2.

In an embodiment, one of the first electrodes EL1 may be disposed between a first light emitting pattern ELS1 and the first pattern CCL1, which overlap the first light emitting area PXA-R, and another of the first electrodes EL1 may be disposed between the first light emitting pattern ELS1 and the second pattern CCL2, which overlap the second light emitting area PXA-G.

In an embodiment, a portion of each of the first electrodes EL1 may be covered by the second barrier wall BK2, however, the present disclosure should not be limited thereto or thereby. As described later, when the second barrier wall BK2 is formed before the first electrodes EL1 are formed, the first electrodes EL1 may not be covered by the second barrier wall BK2.

The first electrodes EL1 may include indium tin oxide (ITO). The first electrodes EL1 may be an optically transmissive electrode. The first electrodes EL1 may have a transmittance of about 90% or more with respect to a light.

The light emitting pattern ELS may include the first light emitting patterns ELS1 and the second light emitting pattern ELS2. The first light emitting patterns ELS1 may be disposed in the second-first openings OP2-1. The second light emitting pattern ELS2 may be disposed in the second-second opening OP2-2. Each of the first light emitting patterns ELS1 may have a thickness ElH greater than a thickness E2H of the second light emitting pattern ELS2.

The light emitting pattern ELS may emit the source light. As an example, the light emitting pattern ELS may generate the source light with the blue color. The light emitting pattern ELS may generate a light in a wavelength range equal to or greater than about 410 nm and equal to or smaller than about 480 nm.

Each of the first light emitting patterns ELS1 and the second light emitting pattern ELS2 may include a light emitting layer, however, the invention should not be limited thereto or thereby. That is, each of the first light emitting patterns ELS1 and the second light emitting pattern ELS2 may have a Tandem structure. As an example, each of the first light emitting patterns ELS1 and the second light emitting pattern ELS2 may include a light emitting layer generating the green light in addition to the light emitting layer generating the blue light. Accordingly, the luminance of the display panel DP may be enhanced.

The light emitting pattern ELS may include a fluorescent or phosphorescent material. According to an embodiment, the light emitting pattern ELS may include anthracene derivatives, pyrene derivatives, fluoranthene derivatives, chrysene derivatives, dihydrobenzanthracene derivatives, or triphenylene derivatives.

In an embodiment, the third layer PT3 may be disposed on the second layer PT2. The third layer PT3 may improve the light efficiency by micro-resonating the light provided from the first layer PT1 or the second layer PT2. In FIG. 6, a stack structure of elements included in the third layer PT3 is omitted, and the structure and function of the third layer PT3 will be described with reference to FIGS. 7A and 7B.

In an embodiment, the fourth layer PT4 may be disposed on the third layer PT3. The fourth layer PT4 may include the third barrier wall BK3 and color filters CF1, CF2, and CF3.

In an embodiment, the third barrier wall BK3 may be disposed on the third layer PT3. The third barrier wall BK3 may be provided with the third-first openings OP3-1 and the third-second opening OP3-2, which are defined therethrough. The third barrier wall BK3 may include an organic light blocking material or an inorganic organic light blocking material, which includes a black pigment or a black dye. The third barrier wall BK3 may prevent a color mixture between the light emitting areas PXA-R, PXA-G, and PXA-B.

In an embodiment, the first color filter CF1 may be disposed in one of the third-first openings OP3-1 and may overlap the first pattern CCL1. The second color filter CF2 may be disposed in the other of the third-first openings OP3-1 and may overlap the second pattern CCL2. The third color filter CF3 may be disposed in the third-second opening OP3-2 and may overlap the second light emitting pattern ELS2.

Each of the color filters CF1, CF2, and CF3 may transmit a light of a specific wavelength range and may block a light outside the specific wavelength range. In the present embodiment, the first color filter CF1 may transmit the red light, the second color filter CF2 may transmit the green light, and the third color filter CF3 may transmit the blue light. Each of the color filters CF1, CF2, and CF3 may include a polymer photosensitive resin and a colorant. The colorant may include a pigment or dye. The first color filter CF1 may include a red pigment or a red dye, the second color filter CF2 may include a green pigment or a green dye, and the third color filter CF3 may include a blue pigment or a blue dye, however, the present disclosure should not be limited thereto or thereby. As an example, in a case where the second light emitting pattern ELS2 emits only the blue light, the third color filter CF3 may include an optically transparent resin.

FIG. 7A is a cross-sectional view illustrating the first light emitting area PXA-R of the display panel DP, according to an embodiment. FIG. 7B is a conceptual view schematically illustrating a travel of light within the third layer PT3, according to an embodiment.

In an embodiment, FIG. 7A illustrates paths through which lights travel within the first layer PT1 and the second layer PT2 as a representative example. For the convenience of explanation, one first quantum dot QD1 included in the first pattern CCL1 is shown, and the other first quantum dots QD1 are omitted.

Hereinafter, the stack structure and function of the third layer PT3 will be described with reference to FIGS. 7A and 7B.

In an embodiment, the third layer PT3 may include half mirror layers HM1, HM2, and HM3 and medium layers MX1 and MX2. The first half mirror layer HM1, the first medium layer MX1, the second half mirror layer HM2, the second medium layer XM2, and the third half mirror layer HM3 may be sequentially stacked along the third direction DR3.

The third layer PT3 may micro-resonate the source light emitted from the light emitting pattern ELS and the light emitted from the quantum dots QD1 and QD2 using two Fabry-Perot interferometers and may function to increase an intensity of the light in a specific wavelength range.

In detail, the first half mirror layer HM1, the first medium layer MX1, and the second half mirror layer HM2 may form one Fabry-Perot interferometer, and the second half mirror layer HM2, the second medium layer MX2, and the third half mirror layer HM3 may form the other Fabry-Perot interferometer.

In an embodiment, the source light emitted from the light emitting layer ELS and the light emitted from the first quantum dot QD1 or the second quantum dot QD2 may be repeatedly reflected and resonated within the third layer PT3. Thus, the display panel DP, according to an embodiment, may increase a light emission efficiency of the light in the specific wavelength range.

In an embodiment, each of the half mirror layers HM1, HM2, and HM3 may include a metal material. Each of the half mirror layers HM1, HM2, and HM3 may include aluminum (Al), silver (Ag), magnesium (Mg), an alloy of magnesium (Mg) and silver (Ag), etc. However, the type of metal material contained in each of the half mirror layers HM1, HM2, and HM3 should not be particularly limited as long as the half mirror layers HM1, HM2, and HM3 have the light reflectivity and transmittivity.

In an embodiment, the medium layers MX1 and MX2 may include an optically transparent resin or silicon nitride.

In an disclosure, the first half mirror layer HM1 may be referred to as a second electrode, and the first medium layer MX1 may be referred to as a second electrode protective layer. In addition, the second half mirror layer HM2 and the third half mirror layer HM3 may be referred to as a first encapsulation inorganic layer and a second encapsulation inorganic layer, respectively, and the second medium layer MX2 may be referred to as an encapsulation organic layer.

In an embodiment, the light emitting element OLED may be disposed on the first layer PT1. The light emitting element OLED may include the first electrode EL1, the first light emitting pattern ELS1, the second electrode HM1, and the second electrode protective layer MX1. The first electrode EL1 and the first half mirror layer HM1 may function as an anode and a cathode, respectively.

An encapsulation layer TFE may be disposed on the light emitting element OLED. The encapsulation layer TFE may include the first encapsulation inorganic layer HM2, the encapsulation organic layer MX2, and the second encapsulation inorganic layer HM3. The encapsulation layer TFE may prevent moisture and oxygen from entering the light emitting element OLED.

That is, according to the display panel DP, the third layer PT3 may perform some of functions of the encapsulation layer TFE and the light emitting element OLED. Therefore, the stack structure of the display panel DP may be simplified, and a manufacturing time and cost of the display panel DP may be reduced.

Referring to FIG. 7A, the source light may be emitted from the first light emitting pattern ELS1. In an embodiment, the source light may be the blue light. It is desirable for all of the emitted source light to reach the first quantum dot QD1, but some of the source light may not reach the first quantum dot QD1 immediately after emission.

The source light may be repeatedly reflected and re-reflected between the first portion RT1 and the half mirror layers HM1, HM2, and HM3. FIG. 7A illustrates a source light B1 emitted from the first light emitting pattern ELS1 and reflected by the first portion RT1 and a source light B2 reflected by the first half mirror layer HM1. Accordingly, the proportion of the source light that finally reaches the first quantum dot QD1 may increase, and thus, the efficiency of light recycling may be improved.

In an embodiment, the first quantum dot QD1 may absorb the light provided thereto and may emit a light having another wavelength. As an example, the first quantum dot QD1 may absorb the source light and may emit the red light. The first quantum dot QD1 may absorb the source light and become excited, and then, the first quantum dot QD1 may emit the red light when falls to a ground state. Since the first quantum dot QD1 exhibits a discontinuous energy band gap due to the quantum confinement effect, the display panel DP may provide the light with a high color purity.

In an embodiment and referring to FIG. 7A, the first quantum dot QD1 may have an anisotropic light radiation property. That is, the first quantum dot QD1 may have the property of randomly radiating the light in various directions.

However, since the display panel DP includes the first portion RT1 that is in contact with the side surface CIS of the first pattern CCL1 as well as the bottom surface C1B of the first pattern CCL1, the display panel DP may reflect the light randomly radiated from the first quantum dot QD1 to various directions. FIG. 7A illustrates that a red light R1 emitted from first quantum dot QD1 travels toward the third layer PT3 after being reflected by a first surface RU of the first portion RT1 and a red light R2 emitted from first quantum dot QD1 travels toward the third layer PT3 after being reflected by a second surface RS of the first portion RT1 as a representative example. Accordingly, the display panel DP may have high light emission efficiency.

Referring to FIG. 7B, in an embodiment, a light incident to the first half mirror layer HM1 of the third layer PT3 after passing through the first layer PT1 and the second layer PT2 may be defined as a first transmissive light L1, and a light reflected by the first half mirror layer HM1 may be defined as a first reflective light L1′. In addition, a light incident to the second half mirror layer HM2 after passing through the first half mirror layer HM1 may be defined as a second transmissive light L2, and a light reflected by the second half mirror layer HM2 may be defined as a second reflective light L2′. In addition, a light incident to the third half mirror layer HM3 after passing through the second half mirror layer HM2 may be defined as a third transmissive light L3, and a light reflected by the third half mirror layer HM3 may be defined as a third reflective light L3′. In addition, a light traveling in the third direction DR3 after passing through the third half mirror layer HM3 may be defined as a fourth transmissive light L4.

When the first transmissive light L1 passes through the third layer PT3, more than about 70% of the blue light may be reflected while more than about 40% of each of the green light and the red light may transmit the third layer PT3. As described above, the first transmissive light L1 trapped within the first layer PT1 and the second layer PT2 may repeatedly reflected or may transmit, and through this, most of the blue light that is not converted into the red light or the green light may be converted into the red light or the green light. Accordingly, the third layer PT3 may improve the color purity of the red light or the green light. In addition, since the first reflective light L1′ is provided to the first layer PT1 (refer to FIG. 7A) and the second layer PT2 (refer to FIG. 7A) again, the blue wavelength light among the first reflective light L1′ may be converted into the red light through the light recycling process by the first quantum dot QD1 (refer to FIG. 7A).

FIG. 7C is a cross-sectional view illustrating the third light emitting area PXA-B of the display panel DP, according to an embodiment. FIG. 7C is a view illustrating paths through which lights travel path like a first path Bla and a second path Blbwithin the second layer PT2.

In an embodiment, the third layer PT3 may be disposed in the third light emitting area PXA-B in addition to the light emitting areas PXA-R and PXA-G. That is, the third layer PT3 may be disposed entirely over the light emitting areas PXA-R, PXA-G, and PXA-B without being patterned. Accordingly, a light emission efficiency of a light L-B emitted from the third light emitting area PXA3 may be slightly reduced, however, the manufacturing time and cost for the display panel DP may be reduced since a process of patterning the third layer PT3 is omitted.

However, the invention should not be limited thereto or thereby. As an example, the third layer PT3 may be removed from an area overlapping the third light emitting area PXA-B.

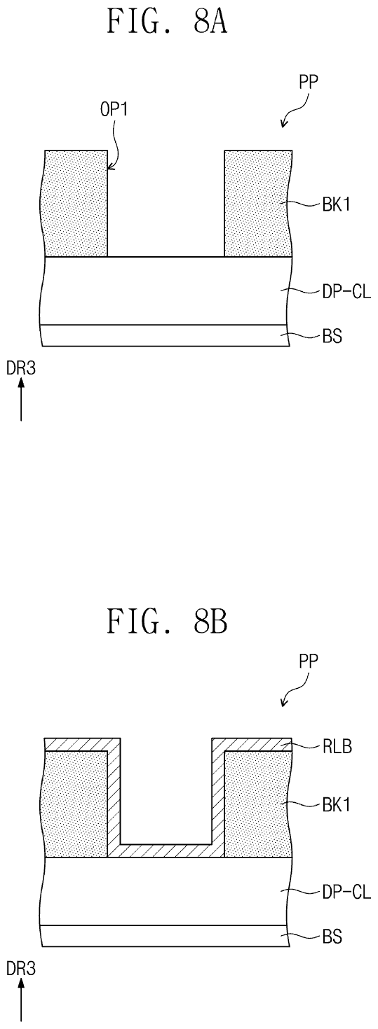

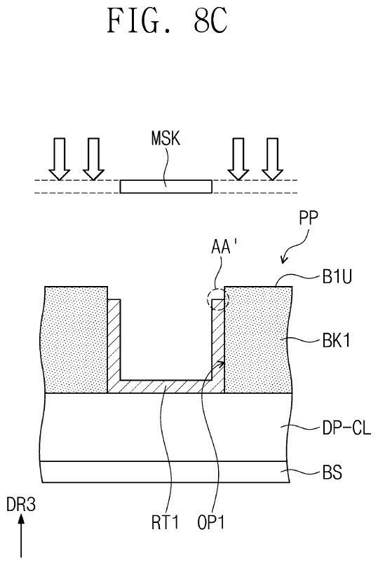

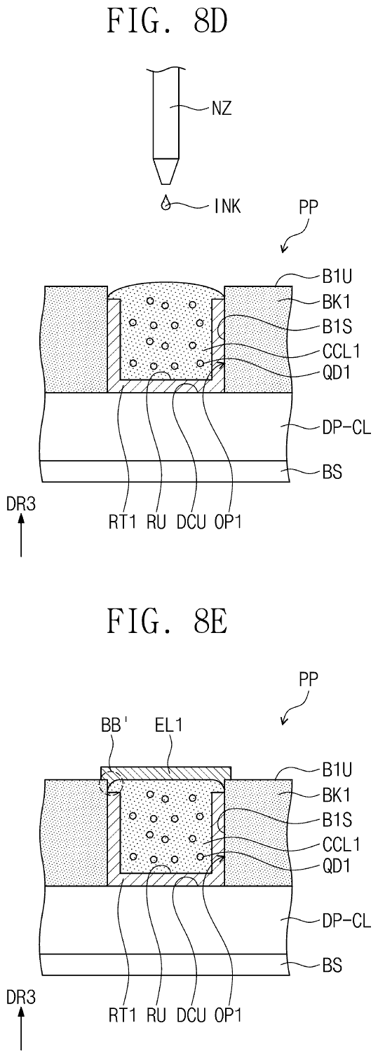

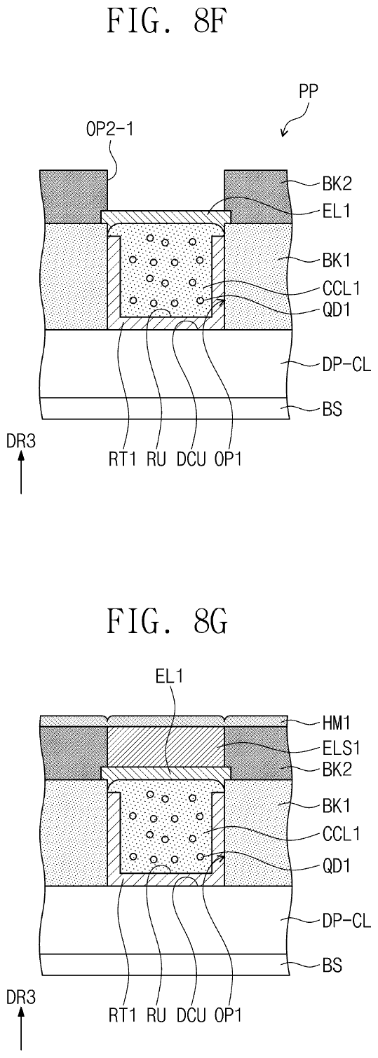

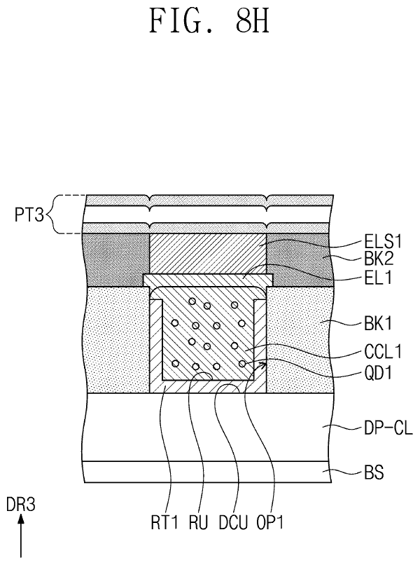

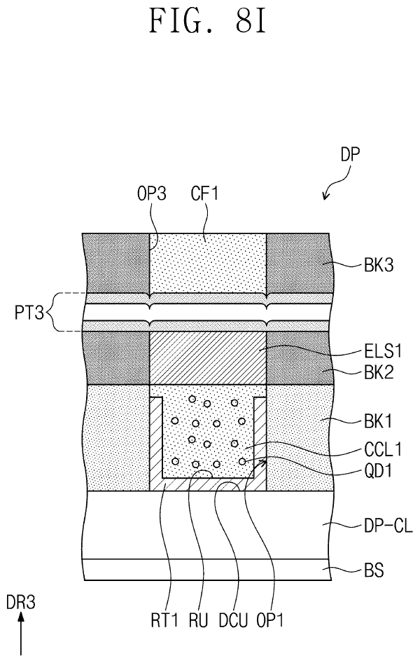

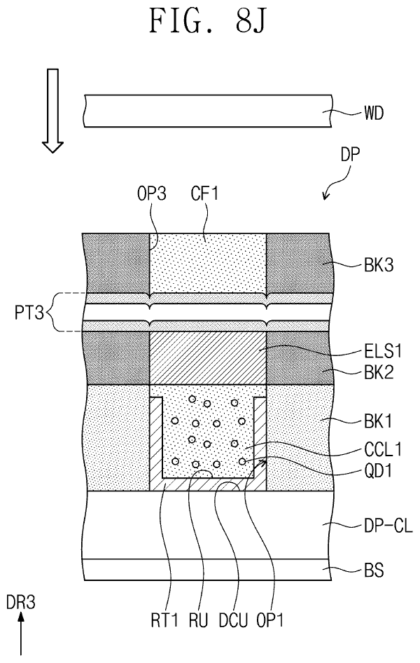

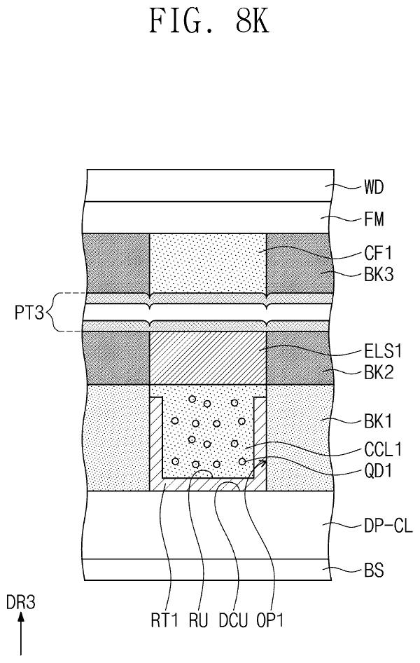

FIGS. 8A to 8K are views illustrating a method of manufacturing the display device, according to an embodiment. In FIGS. 8A to 8K, the same/similar reference numerals denote the same/similar elements in FIGS. 1 to 7C, and thus, detailed descriptions of the same/similar elements will be omitted.

In an embodiment, the manufacturing method of the display device may include providing the base layer and the circuit element layer disposed on the base layer and including transistors, forming the first barrier wall through which the first openings are defined on the circuit element layer, forming the reflective members on the first barrier wall, removing at least a portion where the reflective members are in contact with the upper surface of the first barrier wall, forming the patterns including the quantum dot on the reflective members covering the first opening, forming the first electrodes on the patterns, forming the second barrier wall through which the second-first openings are defined to overlap the first openings on the first barrier wall, forming the first light emitting patterns in the second-first openings, and forming the first half mirror layer on the second barrier wall. Hereinafter, the manufacturing method of the display device will be described with reference to FIGS. 8A to 8K.

In an embodiment and referring to FIG. 8A, the manufacturing method of the display panel may include providing a preliminary display panel PP. In an embodiment, the preliminary display panel PP may be used for the manufacturing process of the display panel DP (refer to FIG. 2) and may be defined as a general term that refers to the display panel DP (refer to FIG. 2) in an unfinished state.

In an embodiment, the circuit element layer DP-CL may be formed by forming the insulating layer, the semiconductor layer, and the conductive layer using the coating or depositing process and selectively patterning the insulating layer, the semiconductor layer, and the conductive layer through photolithography and etching processes to form the semiconductor pattern, the conductive pattern, and the signal line.

The first barrier wall BK1 may be formed on the circuit element layer DP-CL. The forming of the first opening OP1 through the first barrier wall BK1 may be performed by a conventional etching process. As an example, the first opening OP1 may be formed through the first barrier wall BK1 by a dry etching process.

In an embodiment and referring to FIG. 8B, the manufacturing method of the display device may include forming a reflective member base RLB on the first barrier wall BK1. As an example, the reflective member base RLB may be formed on the first barrier wall BK1 through a sputtering process or a chemical vapor deposition (CVD) process.

In an embodiment and referring to FIG. 8C, the manufacturing method of the display device may include removing at least a portion of the reflective member base RLB, which is in contact with an upper surface BIU of the first barrier wall BK1. As an example, the reflective member base RLB (refer to FIG. 8B) may be patterned by forming a photoresist layer (not shown) on the reflective members, aligning a mask MSK on the preliminary display panel PP, and exposing and developing the reflective members.

In an embodiment, a portion of the reflective member base RLB (refer to FIG. 8B), which is disposed inside the first opening OP1, may be etched during the patterning process. An area AA′ of FIG. 8C shows that the portion of the reflective member base RLB (refer to FIG. 8B) disposed inside the first opening OP1 is etched. However, the invention should not be limited thereto or thereby, and different from the structure shown in FIG. 8C, the portion of the reflective member base RLB disposed inside the first opening OP1 may not be etched.

In an embodiment and referring to FIG. 8D, the manufacturing method of the display device may include the forming of the first patterns CCL1 including the quantum dot QD1 on the first portion RT1 to cover the first opening OP1. In detail, the inkjet process that sprays the ink including the quantum dot QD1 to the first opening OP1 through a nozzle NZ may be performed.

The surfaces BIS and BIU of the first barrier wall BK1 may have a liquid repellency. In detail, the surfaces BIS and BIU of the first barrier wall BK1 may have a surface energy greater than about 12 dyne/cm and smaller than about 20 dyne/cm. As described above, when the surfaces BIS and BIU of the first barrier wall BK1 have the liquid repellency, an overflow phenomenon where the sprayed ink INK flows outward from the first opening OP1 may be prevented.

In an embodiment, the first barrier wall BK1 may include a material with liquid repellency. The first barrier wall BK1 may include a material with low surface energy. As an example, the first barrier wall BK1 may include fluorine having a molecular weight of about 15000 g/mol or less.

In an embodiment and referring to FIGS. 8E and 8F, the manufacturing method of the display device may include the forming of the first electrode EL1 on the first pattern CCL1 and forming the second barrier wall BK2 covering a portion of the first electrode EL1 and provided with the second-first opening OP2-1 defined therethrough.

An area BB′ of FIG. 8E shows that a separation space is formed between the first pattern CCL1 and the first barrier wall BK1 due to the liquid repellency of the first barrier wall BK1.

In an embodiment and referring to FIGS. 8G and 8H, the manufacturing method of the display device may include the forming of the first light emitting patterns ELS1 in the second-first openings and then the forming of the first half mirror layer HM1 on the second barrier wall BK2 and the first light emitting pattern ELS1. The first half mirror layer HM1 may be formed through the sputtering process or the chemical vapor deposition (CVD) process.

Then, components included in the third layer PT3 except for the first half mirror layer HM1 may be stacked on the first half mirror layer HM1. As an example, the first medium layer MX1, the second half mirror layer HM2, the second medium layer MX2, and the third half mirror layer HM3 described with reference to FIG. 7A may be formed on the first half mirror layer HM1.

In an embodiment and referring to FIGS. 8I to 8K, the manufacturing method of the display device may include forming the third barrier wall BK3 through which the third opening OP3 is defined on the third layer PT3, forming the first color filter CF1 in the third opening OP3, aligning the window WD with the display panel DP, and pressing the window WD to the display panel DP with the filler FM interposed therebetween.

However, the invention should not be limited thereto or thereby. Although not shown in figures, the third barrier wall BK3 and the color filter may be formed on the window WD, and then the window WD and the third barrier wall BK3 may be attached to the preliminary-display panel PP after being disposed on the preliminary-display panel PP.

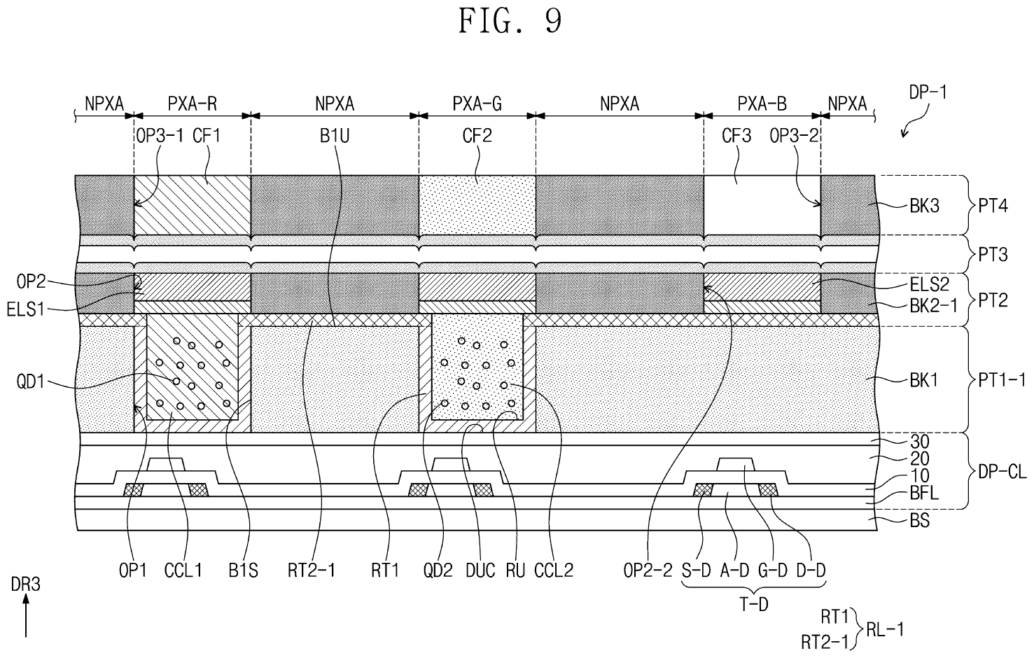

FIG. 9 is a cross-sectional view of a display panel DP-1, according to an embodiment. In FIG. 9, the same/similar reference numerals denote the same/similar elements in FIGS. 1 to 7C, and thus, detailed descriptions of the same/similar elements will be omitted.

In an embodiment, the display panel DP-1 may include a base layer BS, a circuit element layer DP-CL, a first layer PT1-1, a second layer PT2, a third layer PT3, and a fourth layer PT4.

The first layer PT1-1 may include a first barrier wall BK1 through which first openings OP1 are defined, a reflective member RL-1, a first pattern CCL1, and a second pattern CCL2.

The reflective member RL-1 may include a first portion RT1 and a second portion RT2-1. The first portion RT1 may cover a side surface BIS of the first barrier wall BK1, which defines the first openings OP1, and an upper surface DCU of the circuit element layer DP-CL, which is exposed through the first openings OP1. The second portion RT2-1 may cover an upper surface BIU of the first barrier wall BK1. However, the first portion RT1 and the second portion RT2-1 are merely separated for the convenience of explanation, and the reflective member RL-1 may be provided as a continuous single body on the first barrier wall BK1.

A first electrode EL1-1 may overlap at least a portion of the reflective member RL-1. However, the first electrode EL1-1 and the reflective member RL-1 may be electrically separated from each other. As an example, the first electrode EL1-1 and the reflective member RL-1 may be spaced apart from each other with a separate insulating layer interposed therebetween.

A second barrier wall BK2 may be disposed on the second portion RT2-1. The second barrier wall BK2 may be disposed spaced apart from the first barrier wall BK1 with the second portion RT2-1 interposed therebetween.

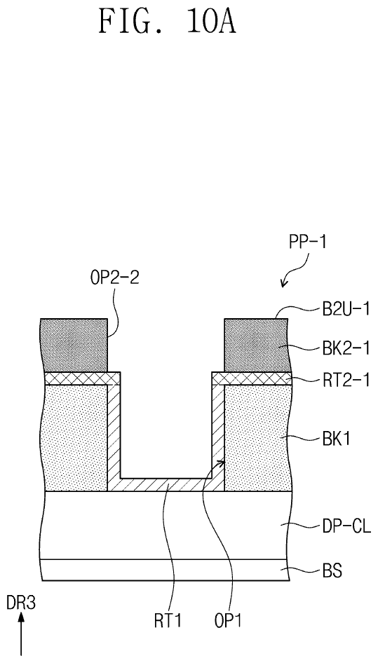

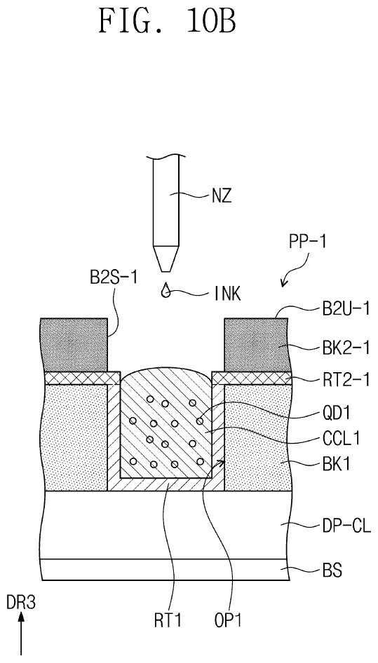

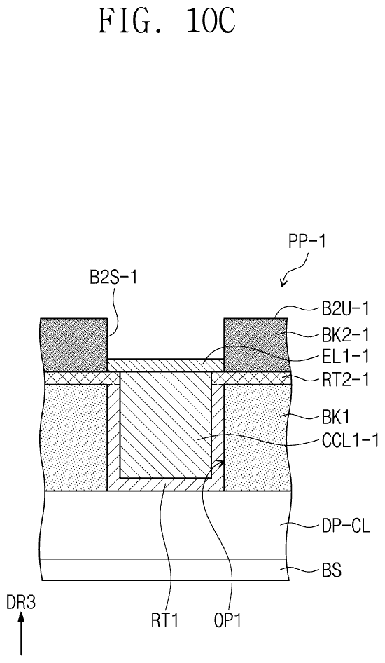

FIGS. 10A to 10C are views illustrating a method of manufacturing a display device, according to an embodiment.

In an embodiment, the manufacturing method of the display device may include providing the base layer and the circuit element layer disposed on the base layer and including transistors, forming the first barrier wall through which the first openings are defined on the circuit element layer, forming the reflective members on the first barrier wall, removing at least a portion of the reflective members, which is in contact with the upper surface of the first barrier wall, forming the second barrier wall through which second openings are defined to overlap the first openings on the first barrier wall, forming patterns including a quantum dot on the reflective members covering the first opening, forming first electrodes on the patterns, forming light emitting patterns in the second openings, and forming a first half mirror layer on the second barrier wall.

In an embodiment, a preliminary display panel PP-1 described with reference to FIGS. 10A to 10C are formed through the same/similar processes as those described with reference to FIGS. 8A and 8K, and thus, the same/similar descriptions will be omitted.

In an embodiment and referring to FIG. 10A, the manufacturing method of the display device may include the forming of the second barrier wall BK2-1 through which the second openings OP2-2 are defined to overlap the first openings OP1 on the first barrier wall BK1.

In an embodiment and referring to FIG. 10B, the first pattern CCL1 including the quantum dot QD may be formed on the first portion RT1 covering the first opening OP1. The forming of the first pattern CCL1 may include spraying an ink INK including the quantum dot QD to the first opening OP1 through a nozzle NZ.

In an embodiment and referring to FIG. 10B, the manufacturing method of the display device may include the forming of the first patterns CCL1 including the quantum dot QD1 on the first portion RT1 covering the first opening OP1. In detail, the spraying of the ink INK including the quantum dot QD1 to the first opening OP1 through the nozzle NZ may be performed.

In an embodiment, surfaces B2U-1 and B2S-1 of the second barrier wall BK2-1 may have a liquid repellency. Preferably, the surfaces B2U-1 and B2S-1 of the second barrier wall BK2-1 may have a surface energy greater thana about 12 dyne/cm and smaller than about 20 dyne/cm. As described above, when the surfaces B2U-1 and B2S-1 of the second barrier wall BK2-1 have the liquid repellency, the overflow phenomenon in which the sprayed ink INK flows outward the first opening OP1 may be effectively prevented.

In an embodiment, the second barrier wall BK2-1-1 may include a material with liquid repellency. The second barrier wall BK2-1-1 may include a material with low surface energy. As an example, the second barrier wall BK2-1-1 may include fluorine having a molecular weight of about 15000 g/mol or less.

In an embodiment and referring to FIG. 10C, the manufacturing method of the display device may include forming a first electrode EL1-1 on the first pattern CCL1.

In an embodiment, the first electrode EL1-1 may be formed by a sputtering process or a chemical vapor deposition (CVD) process. In this case, since the first electrode EL1-1 is formed after the second barrier wall BK2-1-1 is formed, the first electrode EL1-1 may not be covered by the second barrier wall BK2-1-1, however, the invention should not be limited thereto or thereby.

Although embodiments of the invention have been described, it is understood that the invention should not be limited to these embodiments but rather various changes and modifications can be made by one of ordinary skill in the art within the spirit and scope of the invention. Therefore, the invention should not be limited to any single embodiment described herein.

What is claimed is:

1. A display panel comprising:
a base layer comprising first, second, and third light emitting areas and a non-light-emitting area disposed adjacent to the first, second, and third light emitting areas;
a circuit element layer disposed on the base layer and comprising a transistor;
a first layer disposed on the circuit element layer and comprising a first barrier wall provided with first openings defined therethrough, a reflective member comprising a first portion disposed in the first openings and covering an upper surface of the circuit element layer and side surfaces of the first barrier wall which define the first openings, a first pattern comprising a first quantum dot, wherein the first pattern is disposed on the first portion overlapping the first light emitting area, and a second pattern comprising a second quantum dot, wherein the second pattern is disposed on the first portion overlapping the second light emitting area; and
a second layer disposed on the first layer and comprising a second barrier wall provided with second-first openings defined therethrough to overlap the first openings and first light emitting patterns respectively disposed in the second-first openings.

2. The display panel of claim 1, wherein the first barrier wall is in contact with the upper surface of the circuit element layer.

3. The display panel of claim 1, wherein the reflective member comprises a metal material.

4. The display panel of claim 1, wherein the first barrier wall has a surface energy, wherein the surface energy is greater than about 12 dyne/cm and smaller than about 20 dyne/cm.

5. The display panel of claim 1, wherein the second layer further comprises first electrodes, wherein one of the first electrodes is disposed between one of the first light emitting patterns and the first pattern, and wherein another of the first electrodes is disposed between another of the first light emitting patterns and the second pattern.

6. The display panel of claim 5, wherein the first electrodes comprise an indium tin oxide and has a light transmittance equal to or greater than about 90%.

7. The display panel of claim 1, further comprising a third layer disposed on the second layer, wherein the third layer comprises:
first, second, and third half mirror layers;
a first medium layer disposed between the first half mirror layer and the second half mirror layer; and
a second medium layer disposed between the second half mirror layer and the third half mirror layer.

8. The display panel of claim 7, wherein each of the first and second medium layers comprises a resin or silicon nitride having a light transmissivity.

9. The display panel of claim 7, further comprising a fourth layer disposed on the third layer, wherein the fourth layer comprises:
a third barrier wall provided with third-first openings defined therethrough;
a first color filter disposed in one of the third-first openings and overlapping the first pattern; and
a second color filter disposed in another of the third-first openings and overlapping the second pattern.

10. The display panel of claim 9, wherein the first color filter has a light transmissivity with respect to a red light, and the second color filter has a light transmissivity with respect to a green light.

11. The display panel of claim 9, wherein the second barrier wall is provided with a second-second opening defined therethrough to overlap the third light emitting area, wherein the second layer further comprises a second light emitting pattern disposed in the second-second opening and a first electrode disposed between the first barrier wall and the second light emitting pattern, and wherein the reflective member further comprises a second portion overlapping the third light emitting area and disposed between the first electrode and the first barrier wall.

12. The display panel of claim 11, wherein the third barrier wall is provided with a third-second opening defined therethrough to overlap the second light emitting pattern, and wherein the fourth layer further comprises a third color filter disposed in the third-second opening and having a light transmissivity with respect to a blue light.

13. The display panel of claim 9, wherein the second and third barrier walls comprise a light blocking material.

14. The display panel of claim 1, wherein the reflective member further comprises a second portion covering an upper surface of the first barrier wall, and wherein the first portion and the second portion are provided integrally with each other.

15. The display panel of claim 1, wherein the second barrier wall has a surface energy greater than about 12 dyne/cm and smaller than about 20 dyne/cm.

16. A method of manufacturing a display device, comprising:
providing a base layer and a circuit element layer disposed on the base layer, wherein the circuit element layer comprises transistors;
forming a first barrier wall through which first openings are defined on the circuit element layer;
forming a reflective member base on the first barrier wall;
removing at least a portion of the reflective member base, which is in contact with an upper surface of the first barrier wall, to form a reflective member;
forming a first pattern comprising a quantum dot on the reflective member covering the first openings;
forming first electrodes on the first pattern;
forming a second barrier wall through which second-first openings are defined to overlap the first openings on the first barrier wall;
forming first light emitting patterns within the second-first openings; and
forming a half mirror layer on the second barrier wall.

17. The method of claim 16, wherein the forming of the first pattern comprises spraying an ink comprising the quantum dot into the first opening, and wherein the first barrier wall has a surface energy greater than about 12 dyne/cm and smaller than about 20 dyne/cm.

18. The method of claim 16, further comprising forming a second light emitting pattern, wherein the forming of the second barrier wall further comprises forming a second-second opening that does not overlap the first openings, and wherein the second light emitting pattern is formed in the second-second opening after the forming of the second barrier wall.

19. A method of manufacturing a display device, comprising:
providing a base layer and a circuit element layer disposed on the base layer and comprising transistors;
forming a first barrier wall through which first openings are defined on the circuit element layer;
forming a reflective member on the first barrier wall;
forming a second barrier wall through which second openings are defined to overlap the first openings on the first barrier wall;
forming patterns comprising a quantum dot on the reflective member covering the first openings;
forming first electrodes on the patterns;
forming light emitting patterns in the second openings; and
forming a first half mirror layer on the second barrier wall.

20. An electronic device for providing an image, comprising:
A display panel; and
A window disposed on the display panel;
wherein the display panel comprises:
a base layer comprising first, second, and third light emitting areas and a non-light-emitting area disposed adjacent to the first, second, and third light emitting areas;
a circuit element layer disposed on the base layer and comprising a transistor;
a first layer disposed on the circuit element layer and comprising a first barrier wall provided with first openings defined therethrough, a reflective member comprising a first portion disposed within the first openings and covering an upper surface of the circuit element layer and side surfaces of the first barrier wall which define the first openings, a first pattern comprising a first quantum dot and disposed on the first portion overlapping the first light emitting area, and a second pattern comprising a second quantum dot and disposed on the first portion overlapping the second light emitting area; and
a second layer disposed on the first layer and comprising a second barrier wall provided with second-first openings defined therethrough to overlap the first openings and first light emitting patterns respectively disposed in the second-first openings.
